(19) United States
(12) Patent Application Publication
(10) Pub. No.: US 2007/0017902 A1
(43) Pub. Date: Jan. 25, 2007

(54) Method for the chemical treatment of copper surfaces for the removal of carbonaceous residues

(75) Inventors: Sebastien Petitdidier, Gieres (FR); Alain Inard, St. Nazaire Les Eymes (FR)

Correspondence Address: JENKENS & GILCHRIST, PC, 1445 ROSS AVENUE, SUITE 3200, DALLAS, TX, 75202, US

(73) Assignee: STMicroelectronics S.A., Montrouge (FR)

(21) Appl. No.: 11/187,707

(22) Filed: Jul. 22, 2005

(51) Int. Cl. B44C 1/22; C03C 25/68; H01L 21/461

(52) U.S. Cl. 216/88; 438/692; 216/83

(57) ABSTRACT

A method for the treatment of copper surfaces on a semiconductor wafer for the removal of carbonaceous residues, these being obtained during a chemical-mechanical polishing operation, includes a water rinsing of the wafer followed by a chemical rinsing of the wafer using a solution containing a corrosion inhibitor and an organic acid.

### BACKGROUND OF THE INVENTION

1. Technical Field of the Invention

The present invention relates to integrated circuits and more particularly to the treatment of copper surfaces.

2. Description of Related Art

The production of integrated circuits for microelectronics constantly requires, at various steps in the fabrication, a surface treatment of wafers with features, so as to obtain a surface free of defects of any kind (structural defects, the presence of impurities, the adhesion of foreign nanoparticles). With the elementary dimensions of the components of integrated circuits continuing to decrease, criteria relating to the transformations brought about by these treatments are becoming increasingly stringent.

One of the defects responsible for a drop in yield is the presence of carbonaceous residues on copper surfaces. The density of these residues on the material varies widely, from 0.1 to 100 defects/cm².

Conventionally, wafers with features formed from copper and dielectric, such as silicon oxide, undergo a chemical-mechanical polishing operation followed by chemical rinsing. The latter operation makes it possible to obtain dielectric and copper surfaces that are free of impurities of any kind. In addition, this treatment is used to prepare the surface by reducing the structural imperfections and by functionalizing the surface connections, that is to say by modifying the chemical nature of the surface, while still avoiding corrosion phenomena.

At the present time, chemical-mechanical polishing takes place in the presence of a corrosion inhibitor in an alkaline medium, generally in the presence of hydrogen peroxide, and of abrasive nanoparticles. The corrosion inhibitor conventionally used is a triazole derivative, which allows the formation of an insoluble polymer film on the surface of the copper oxide, limiting anode dissolution of the copper.

This chemical-mechanical polishing is generally followed by rinsing in the presence of a corrosion inhibitor, and then rinsing with water, and finally a cleaning step in an acid or basic aqueous medium in a separate cleaning apparatus. However, dissolution by successive and inappropriate chemical treatments of the copper passivation layer by the triazole derivatives contained in the polishing agent results in the formation of carbonaceous residues.

Research has been carried out for the purpose of removing these carbonaceous residues by mechanical means or by chemical means. However, these methods have not succeeded. The chemical treatments envisaged allow the metal surface beneath the carbonaceous residues to be etched, so as to strip them more easily. A reduction in the density of carbonaceous residues has been observed. But the metal surface now has a much greater number of corrosion defects due to the reduction in the thickness of the passivation layer caused by the chemical treatment.

There is accordingly a need for a rinsing technique that allows the carbonaceous residues formed during the chemical-mechanical polishing to be entirely removed, while still limiting corrosion and passivating the copper surface for the purpose of the subsequent chemical treatments. Advantageously, this rinsing would prevent redeposition of the carbonaceous residues removed and the etching of the dielectric.

### SUMMARY OF THE INVENTION

An embodiment of the present invention relates to a method for the treatment of copper and dielectric surfaces for the removal of carbonaceous residues, following a chemical- mechanical polishing operation, comprising a first step of rinsing with water followed by a second step of chemical rinsing using a corrosion inhibitor and an organic acid.

According to another method of implementation, the chemical rinsing employs a single solution containing a corrosion inhibitor and an organic acid.

According to another method of implementation, the chemical rinsing employs a first solution containing a corrosion inhibitor and a second solution containing an organic acid, these two solutions being used in succession in any order.

Preferably, the corrosion inhibitor is a triazole derivative.

Preferably, the organic acid is chosen from the group consisting of citric acid, glycolic acid and oxalic acid.

The organic acid is preferably present in an amount ranging from 0.5 to 5% by volume relative to the total volume of the solution.

Optionally, the chemical rinsing solution contains a surfactant, such as for example polyethylene glycol, propylene oxide or ethylene oxide.

The surfactant is preferably present in an amount ranging from 0.5 to 3% by volume relative to the total volume of the solution.

Embodiments of the present invention also relate to an integrated circuit comprising at least one copper level treated by the method described above.

In accordance with another embodiment, a method for the treatment of copper surfaces on a semiconductor wafer, following a chemical-mechanical polish, comprises rinsing the wafer with water and then chemically rinsing the wafer using a solution containing a corrosion inhibitor and an organic acid.

In accordance with another embodiment, a method of semiconductor manufacture comprises polishing a semiconductor wafer and then cleaning the polished semiconductor wafer. The step of cleaning comprises polishing the wafer with a slurry, rinsing the wafer with water, rinsing the wafer with a solution containing a corrosion inhibitor and a surfactant, and rinsing the wafer with water.

### BRIEF DESCRIPTION OF THE DRAWINGS

A more complete understanding of the method and apparatus of the present invention may be acquired by reference to the following Detailed Description when taken in conjunction with the accompanying Drawings wherein:

FIG. 1 shows measured density of defects of all types on surfaces as a function of the treatment undergone by these surfaces.

### DETAILED DESCRIPTION OF THE PREFERRED EMBODIMENTS

In accordance with an embodiment, a method comprises water rinsing and chemical rinsing that are carried out after a chemical-mechanical polishing operation, the conditions of which are well known to those skilled in the art.

Rinsing with water prevents acid/base contact between the polishing agent or slurry and the chemical rinsing.

According to one preferred method of implementation, the water rinsing step consists of rinsing for about 20 seconds with a high flow rate, with no movement of the polishing head.

Chemical rinsing allows the copper surface to be partly dissolved so as to strip off the residues from the surface, thanks to the action of an organic acid.

Thus, the partial dissolution of the copper surface does not prevent passivation properties being imparted to this surface, given that it is carried out in the presence of a corrosion inhibitor.

According to another method of implementation, the rinsing employs a single solution containing a corrosion inhibitor with a concentration of less than 5% by volume and an organic acid having a concentration of less than 5 g/l. This solution optionally contains a surfactant with a concentration of less than 5 g/l.

The corrosion inhibitors that can be used in the present invention are described, for example, in S. Tamilmani, W. Huang, S. Raghavan and R. Small, “Corrosion inhibitors for copper in hydroxylamine-based chemistries used for CMP and post-CMP cleaning”, Solid State Phenomena, Vol. 92 (2003), 271 274, in Gy. Vastag, E. Szocs, A. Shaban and E. Kalman, “New inhibitors for copper corrosion”, Pure Appl. Chem. 73(12), (2001), 1861 1869 and in W. Qafsaoui, C. Blanc, N. Pébère, H. Takenouti, A. Srhiri, G. Mankowski, “Quantitative characterization of protective films grown on copper in the presence of different triazole derivative inhibitors”, Electrochemica Acta, 47, (2002), 4339 4346. The disclosures of each of the foregoing references are incorporated herein by reference.

According to another method of implementation, the rinsing employs two solutions, one containing a corrosion inhibitor (as discussed above) with a concentration of less than 5% by volume and, optionally, a surfactant with a concentration of less than 5 g/l, the other containing an organic acid with a concentration of less than 5 g/l. These solutions are used one after the other, in any order.

This treatment is followed by standard steps, that is to say a water rinsing step, followed by a cleaning step in a scrubber using an acidic or basic aqueous solution.

The following non-limiting examples, which constitute advantageous ways of implementing the method according to the invention, will now be described.

The wafers used are formed from a tantalum/tantalum nitride (Ta/TaN) layer with a thickness of 250 Å and a copper barrier layer with a thickness of 1500 Å deposited by PVD (physical vapor deposition) on wafers of preoxidized silicon. The experiments were carried out with films 1.3 μm in thickness annealed in an oven at 400° C., or with films 1.1 μm in thickness already polished using a conventional chemical-mechanical polishing operation.

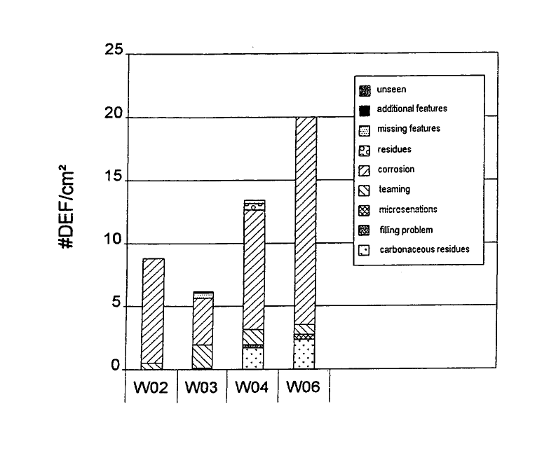

FIG. 1 shows the measured density of defects of all types on surfaces as a function of the treatment undergone by these surfaces.

The wafers denoted by WO4 and WO6, the defects of which have been indicated in FIG. 1, received the standard polishing and cleaning method according to the prior art, described below:
the wafers were polished with a copper polishing agent or slurry on two trays and a barrier slurry on another tray;
the wafers were then rinsed with a solution containing only a corrosion inhibitor (1,2,4 triazole with a concentration of 1-5% by volume relative to the total volume of the solution) and a surfactant (polyethylene glycol with a concentration of 2-3% by volume relative to the total volume of the solution) for 10 seconds with a flow rate of 200 ml/min
they were then rinsed with water for 20 seconds; and
finally, the wafers were transferred to a cleaning apparatus for undergoing a standard cleaning operation.

The wafers denoted by WO2 and WO3, the defects of which have been indicated in FIG. 1, received a standard polishing method followed by a cleaning method according to the present invention described below:
the wafers were polished with a copper slurry on two trays and with a barrier slurry on another tray;
the wafers were then rinsed with water for 20 seconds;
the wafers were then rinsed with a solution containing a corrosion inhibitor (1,2,4 triazole with a concentration of 0.67 3.3% by volume relative to the total volume of the solution) and a surfactant (polyethylene glycol with a concentration of 1.3-2% by volume relative to the total volume of the solution), the defects of which have been indicated, to which solution 10% citric acid (1.43% by volume relative to the total volume of the solution) and a 29% NH₄OH solution (0.17% by volume relative to the total volume of the solution) were added, with a time of 10 seconds with a flow rate of 200 ml/min;
they were then rinsed with water, still on this same tray, for 20 seconds; and
finally, the wafers were transferred to a cleaning apparatus carrying out a standard cleaning operation.

The results shown in FIG. 1 show that the wafers denoted by WO2 and WO3 have no carbonaceous residues and fewer corrosion defects relative to the wafers that have undergone a conventional treatment.

Although preferred embodiments of the method and apparatus of the present invention have been illustrated in the accompanying Drawings and described in the foregoing Detailed Description, it will be understood that the invention is not limited to the embodiments disclosed, but is capable of numerous rearrangements, modifications and substitutions without departing from the spirit of the invention as set forth and defined by the following claims.

What is claimed is:

1. A method for the treatment of copper for the removal of carbonaceous residues, following a chemical-mechanical polishing operation, comprising a first step of rinsing with water followed by a second step of chemical rinsing using a solution containing a corrosion inhibitor and an organic acid.

2. The method according to claim 1, wherein chemical rinsing employs a first solution containing a corrosion inhibitor and a second solution containing an organic acid, these two solutions being used in succession in any order.

3. The method according to claim 1, wherein the corrosion inhibitor is a triazole derivative.

4. The method according to claim 1, wherein the organic acid is selected from the group consisting of citric acid, glycolic acid and oxalic acid.

5. The method according to claim 1, wherein chemical rinsing comprises using a solution containing a surfactant.

6. An integrated circuit manufactured having at least one copper level treated by the method as defined in claim 1.

7. A method, comprising:
polishing a semiconductor wafer; and
cleaning the polished semiconductor wafer, wherein cleaning comprises:
polishing the wafer with a slurry;
rinsing the wafer with water;
rinsing the wafer with a solution containing a corrosion inhibitor and a surfactant; and
rinsing the wafer with water.

8. The method of claim 7 wherein the slurry is a copper slurry.

9. The method of claim 7 wherein the slurry is a barrier slurry.

10. The method of claim 7 wherein the corrosion inhibitor is triazole.

11. The method of claim 7 wherein the surfactant is polyethylene glycol.

12. The method of claim 7 wherein rinsing the wafer with a solution further comprises adding to the solution citric acid and an NH₄OH solution.

13. The method of claim 7 further including transferring the wafer to a cleaning apparatus for carrying out a standard cleaning operation following rinsing with water.

14. A method for the treatment of copper surfaces on a semiconductor wafer, following a chemical-mechanical polish, comprising:
rinsing the wafer with water;
then chemically rinsing the wafer using a solution containing a corrosion inhibitor and an organic acid.

15. The method of claim 14, wherein chemically rinsing comprises:
rinsing the wafer with a solution containing a corrosion inhibitor; and
rinsing the wafer with a solution containing an organic acid.

16. The method of claim 15 wherein the two rinsing steps of claim 15 are performed in succession in any order.

17. The method of claim 14, wherein the corrosion inhibitor is a triazole.

18. The method of claim 14, wherein the organic acid is selected from the group consisting of citric acid, glycolic acid and oxalic acid.

19. The method of claim 14, wherein chemically rinsing comprises adding a surfactant to the solution.

20. The method of claim 14 further comprising, after chemically rinsing, water rinsing of the wafer, followed by cleaning of the wafer using an acidic or basic aqueous solution.
